(19) United States
(12) Patent Application Publication
(10) Pub. No.: US 2024/0280618 A1
(43) Pub. Date: Aug. 22, 2024

(54) SYSTEMS AND METHODS FOR LOAD FORECASTING FOR IMPROVED FORECAST RESULTS BASED ON TUNED WEATHER DATA

(71) Applicant: Arcus Power Corporation, Calgary (CA)

(72) Inventors: Mike QUASHIE, Calgary (CA); Daniel ERHARDT, Calgary (CA)

(73) Assignee: Arcus Power Corporation, Calgary (CA)

(21) Appl. No.: 18/595,861

(22) Filed: Mar. 5, 2024

Related U.S. Application Data
(63) Continuation of application No. PCT/CA2022/051338, filed on Sep. 7, 2022.
(60) Provisional application No. 63/241,226, filed on Sep. 7, 2021.

(51) Int. Cl. G01R 21/133; G01W 1/06

(52) U.S. Cl. CPC G01R 21/133; G01W 1/06

(57) ABSTRACT

The present description relates to systems and methods for load forecasting for improved energy use forecasting based on tuned weather data. The system includes a network of load sensitive weather instruments for producing tuned weather data, and a processor linked to the network of load sensitive weather instruments and receiving the tuned weather data. The processor obtains the tuned weather data from the network of load sensitive weather instruments and is configured to analyse a utility grid specification and correlate the utility grid specification with the tuned weather data to forecast the energy load within the grid

### CROSS-REFERENCE TO RELATED APPLICATIONS

This application is a continuation of PCT Patent Application Serial No. PCT/CA2022/051338, filed on Sep. 7, 2022, which claims priority to U.S. Provisional Patent Application Ser. No. 63/241,226, filed on Sep. 7, 2021, both of which are incorporated by reference herein.

### TECHNICAL FIELD

The present invention relates to systems and methods for load forecasting based on tuned weather data for improved energy use.

### BACKGROUND

A group of power plants, electrical energy consumption devices, and associated infrastructure spread over a geographical area may be referred to as a “utility grid” or an “energy grid”. Variations in power generation by distributed energy resources due to their intermittent nature and related changes in energy consumption can cause variations in operating conditions in a such grids. Large electricity consumers, generators, grid operators and other electricity market participants require accurate electricity demand forecasts to support efficient behaviours and processes necessary for grid optimization.

Typically, there is a need to manage a utility grid such that there is a balance between all available energy resources and energy consumption. “Load forecasting” may be employed to assist in reducing the imbalance between the available energy resources and intended uses thereby maintaining operating conditions in the utility grid within their standard or desired ranges. Load forecasting in a utility grid is an integral part of energy management. Growing penetration of distributed energy resources such as solar photovoltaic (“PV”) power plants, wind power plants, and power storage plants has changed conventional utility practices for generating, transmitting, and distributing electric power.

Typically, operating conditions in a utility grid are managed by an energy management system (“EMS”). The utility grid's energy management system maintains the balance between all available energy resources including centralized energy resources such as coal, natural gas, oil or hydro and distributed energy resources such as solar, wind or storage, and energy uses such as uncontrolled and controlled electrical energy consumption devices. Load forecasting is used by the energy management system to reduce the imbalance between the available energy resources and intended uses thereby maintaining operating conditions in the utility grid within their standard or desired ranges. Due to a variety of factors, load forecasting can be difficult contributing to a decreasing ability to maintain the grid's stability under a variety of conditions.

With weather being a primary influence on energy consumption, highly accurate weather data is a key input for demand forecasts. Currently available weather data is too generic, and in some cases irrelevant, for demand forecasting as it does not reflect the electricity demand patterns in major load areas.

Power systems are usually designed to ensure reliability of the grid and availability of power to consumers during peak demand. Thus, as the peak load/demand increases, system operators invest in assets to undertake their mandate. In addition, most municipalities with generations assets preposition assets in anticipation of peak events, the poorer the estimate or insight into these events, the more fuel is spent to proposition these assets. Furthermore, commercial and industrial (C&I) entities operating in jurisdictions with deregulated electricity markets are access demand charge when they consume electricity during system peak hours of the month or year (depending on the tariff design/structure in the jurisdiction).

As an example, Environment Canada has three weather stations in Calgary: two at the Calgary International Airport, and one at the Springbank Airport. Airports are ideally located in low turbulence areas and do not experience the range of conditions that drives the variability in power demand such as changes in elevation and wind. Demand forecasting models are not calibrated to real world load profiles and will have higher error values. Inaccurate demand forecasts lead to misinformed and inefficient market participant behaviours which prevents the optimization of the electrical grid.

Traditional energy management firms rely on human resources to support a single market. These companies have single market expertise but lack technological solutions that can be scaled or applied to changing electricity markets. Technological solutions that apply predictive analytics to multiple markets, however in many cases these competitors lack market and tariff expertise, resulting in poor forecast performance. The majority of these multiple market competitors are focused on a single segment, and do not have the technology to compete across multiple segments.

Artificial intelligence (“A.I.”) is a field of computer science concerned with creating software systems and methods which can perform activities that are traditionally thought to be the exclusive domain of humans. Research in artificial intelligence (AI) is known to have impacted medical diagnosis, stock trading, robot control, and several other fields. One subfield in this area relates to creating software systems and methods that can predict behavior so that these software systems and methods can replicate human characteristics or traits.

A need therefore exists for load forecasting systems. Accordingly, a solution that addresses, at least in part, the above and other shortcomings is desired. With all the limitations and challenges above comes the need for new technologies and techniques to address the limitations.

### SUMMARY

There remains a need for techniques, systems, methods and devices that can be used for load forecasting for improved forecast results based on tuned weather data from optimally sited, load sensitive weather instrument.

An aspect of the present invention is directed to a system for using artificial intelligence to automatically create and generate load forecasting based on tuned weather data.

According to another aspect of the present invention, there is provided a load forecasting system for improving the performance of an energy or utility grid. The load forecasting system is configured to analyse one or more utility grid specifications including but not limited to the configuration of electrical circuits in the utility grid or advanced metering infrastructure, the applicable geographic areas, time zones and micro-climatological areas, and to provide a load forecast for the utility grid or any portion thereof at least partially based on at least one forecasting variable selected from the group consisting of a weather forecast, such as, but not limited to, a storm warning, wind speed, air density, irradiance, atmospheric turbulence, rain condition, snow condition, air temperature, humidity, etc.

According to another aspect of the present invention is a load forecasting system configured to produce load forecasts at least partially based on at least one environmental condition measured by a sensor. Typical environmental conditions monitored or measured by the environmental condition sensor include wind speed, air density, irradiance, atmospheric turbulence, rain conditions, snow conditions, air temperature, and humidity. Accordingly, the sensor may include an anemometer, an air densimeter, a hygrometer, a thermometer, a rain sensor, a snow sensor, a turbulence sensor, and the like.

In another embodiment of the present invention, there is provided a system for forecasting an energy load within a utility grid based on tuned weather data, the system comprising: (a) a network of load sensitive weather instruments for producing tuned weather data; (b) a processor linked to the network of load sensitive weather instruments and receiving the tuned weather data; wherein the processor obtains the tuned weather data from the network of load sensitive weather instruments and is configured to analyse a utility grid specification and correlate the utility grid specification with the tuned weather data to forecast the energy load within the grid.

In a further preferred embodiment, there is provided the system noted above wherein factors of the utility grid comprise the configuration of electrical circuits in the utility grid, advanced metering infrastructure, the geographic area, time zones, micro-climatological area, historical load data, day of the week, holidays, behind the meter renewable generation, and electricity prices.

In a further preferred embodiment, there is provided the system noted above wherein the tuned weather data comprises storm warnings, wind speed, air density, irradiance, atmospheric turbulence, rain condition, snow condition, air temperature, and humidity that are specific to select locations that are found to be predictive of energy load patterns within an energy grid.

In yet a further preferred embodiment, there is provided the system noted above wherein the processor employs a predictive artificial intelligence or neural network.

In yet a further preferred embodiment, there is provided the system noted above wherein the load sensitive weather instruments comprise an anemometer, an air densimeter, a hygrometer, a thermometer, a rain sensor, a snow sensor, or a turbulence sensor.

In another embodiment of the present invention, there is provided a process for the selection of suitable locations for a plurality of weather instruments, the process comprising: (a) a first processor selecting potential locations for the plurality of weather instruments in order to minimize the difference in a predicted evapotranspiration (ETi) and a referenced theoretical evapotranspiration (ET0) at each of the potential location to produce an initial selection of locations; (b) obtaining weather data for each of the initial selection of locations and transmitting the weather data to a second processer; (c) the second processor receiving the weather data from the initial selection of locations and designing a machine learning model architecture and ensemble based on the weather data arriving at a load model design in order to minimize a mean absolute error (“MAE”) of a predicted load and an actual load at each locations of the initial selection of locations and the second processor assigning a weight to the weather data to produce weighted weather data in the process of designing a machine learning model architecture and ensemble; and (d) the second processor transmitting the MAE and the weighted weather data to the first processor and the first processor observing the weighted weather data at each location of the initial selection of locations and assessing each location of the initial selection of the locations and based thereon selecting further potential locations in order to optimize the initial selection of locations in step (a) and repeating steps (b), (c) and (d) until an equilibrium is found where neither processor has an incentive to change their selections arriving at the suitable locations for the plurality of weather instruments.

In yet another preferred embodiment, process as noted above further provides that in step (c), the equilibrium is found where neither processor has an incentive to change their selections arriving at the suitable locations for the plurality of weather instruments and a final load model design.

According to various aspects of the present invention, a system for forecasting an electrical load within a utility grid is disclosed. The system includes at least one weather station, the at least one weather station configured to gather weather data, and a processor connected to the at least one weather station, the processor configured to receive weather data. The processor comprises a machine learning engine configured to forecast electrical load within a utility based grid on the received weather data, the machine learning engine comprising a training model, the training model generated based on a correlation of weather data from the at least one weather station to electrical load data.

According to various aspects of the present invention, a method for generating a training model for a machine learning engine to forecast an electrical load within a utility grid is disclosed. The method includes deploying at least one weather station in a first position, receiving at a processor, weather data from the at least one weather station for a time frame, and receiving at the processor, electrical load data within the utility grid for the time frame. In addition, the method includes normalizing, by the processor, the weather data and electrical load data, and creating by the processor the training model based on the normalized weather data and electrical load data. Furthermore, the method includes calculating a mean absolute error to determine accuracy of the training model. If the mean absolute error is not within a tolerance, re-deploying the at least one weather station in a second position. If the mean absolute error is within the tolerance, deploying the training model to the machine learning engine.

According to various aspects of the present invention, a method for forecasting an electrical load within a utility grid is disclosed. The method includes receiving at a processor, weather data from at least one weather station at a predetermined time interval, and forecasting an electrical load within a utility grid using a machine learning engine of the processor, the machine learning engine configured to forecast electrical load within a utility based grid on the received weather data, the machine learning engine comprising a training model, the training model generated based on a correlation of weather data from the at least one weather station.

According to various aspects of the present invention, a method for monitoring a training model of a machine learning engine, the machine learning engine configured to forecast an electrical load within a utility grid is disclosed. The method includes receiving an electrical load for the utility grid for a time frame, receiving a previously predicted electrical load for the utility grid for the time frame, and calculating a mean absolute error between the electrical load for the utility grid and the previously predicted electrical load. If the mean absolute error is within a tolerance, providing confirmation that the training model is accurate. If the mean absolute error is not within the tolerance, sending an alert that the training model is not accurate.

According to various aspects of the present invention, a system for anticipating an energy load within a utility grid during a predetermined time interval is disclosed. The system includes a load sensitive weather instrument for detecting and transmitting weather data during the predetermined time interval, and a processor operatively connected to the load sensitive weather instrument and configured to receive the weather data, the processor further comprising a load prediction engine. The processor receives the weather data and passes the weather data through the load prediction engine to determine an anticipated energy load within the utility grid during the predetermined time interval based a correlation between the weather data and pattern data and the processor further configured to transmit the anticipated energy load to a user.

The pattern data may include historical energy load data, day of the week data, holiday data, renewable energy generation data and energy price data.

The predictive engine being trained uses historic weather data and historic energy load data employed by an artificial intelligence-based module.

The load sensitive weather instrument including an anemometer, an air densimeter, a hygrometer, a thermometer, a rain sensor, a snow sensor, or a turbulence sensor.

The system further including a server in communication with the processor to receive the anticipated energy load from the processor and in communication with a client device to transmit the anticipated energy load as an output to the client device, the client device displaying the anticipated energy load to a user.

According to various aspects of the present invention, a process for anticipating an energy load within a utility grid during a predetermined time interval. The process including detecting and transmitting weather data during the predetermined time interval from a load sensitive weather instrument, and receiving the weather data at a processor operatively connected to the load sensitive weather instrument and configured to receive the weather data, the processor further comprising a load prediction engine. The process further including passing the weather data through the load prediction engine to determine an anticipated energy load within the utility grid during the predetermined time interval based a correlation between the weather data and pattern data.

The pattern data may include historical energy load data, day of the week data, holiday data, renewable energy generation data and energy price data.

The predictive engine being trained uses historic weather data and historic energy load data employed by an artificial intelligence-based module.

The load sensitive weather instrument including an anemometer, an air densimeter, a hygrometer, a thermometer, a rain sensor, a snow sensor, or a turbulence sensor.

The process further including the processor transmitting the anticipated energy load to a server and the server transmitting the anticipated energy load as an output to a client device, the client device displaying the anticipated energy load to a user.

### BRIEF DESCRIPTION OF THE DRAWINGS

The embodiments of the present invention shall be more clearly understood with reference to the following detailed description of the embodiments of the invention taken in conjunction with the accompanying drawings, in which:

FIG. 1 illustrates an embodiment of a system for electrical load forecasting for a geographical area;

FIG. 2 illustrates an embodiment of the architecture of the server with the artificial intelligence engine used by the system of FIG. 1;

FIG. 3 illustrates an embodiment of a method to create a training model using the system in FIG. 1;

FIG. 4 illustrates a continuation of the embodiment method of FIG. 3;

FIG. 5 illustrates an embodiment of the present invention detailing the process of selecting the optimal location of the weather instrument;

FIG. 6 illustrates an alternate embodiment of the system for electrical load forecasting for a geographical area/location;

FIG. 7 illustrates an alternate embodiment of the system for electrical load forecasting for a geographical area;

FIG. 8 illustrates an embodiment of server 112 from the system in FIG. 6;

FIG. 9 illustrates an embodiment of a method to create a training model using the system in FIG. 6;

FIG. 10 illustrates an embodiment of a method of electrical load forecasting using the training model;

FIG. 11 illustrates an embodiment of a method of training model monitoring and ensuring proper training data is used for dynamically training the training model;

FIG. 12 illustrates a table of example values of mean absolute error and mean absolute percentage error when renewable solar energy data is both excluded and included;

FIG. 13 illustrates a graph of mean absolute percentage error over several months with renewable solar energy data excluded; and

FIG. 14 illustrates a graph of mean absolute percentage error over several months with renewable solar energy data included.

### DETAILED DESCRIPTION

The description that follows, and the embodiments described therein, is provided by way of illustration of an example, or examples, of particular embodiments of the principles and aspects of the present invention. These examples are provided for the purposes of explanation, and not of limitation, of those principles and of the invention.

It should also be appreciated that the present invention can be implemented in numerous ways, including as a process, method, an apparatus, a system, a device or a method. In this specification, these implementations, or any other form that the invention may take, may be referred to as processes. In general, the order of the steps of the disclosed processes may be altered within the scope of the invention.

It will be understood by a person skilled in the relevant art that in different geographical regions and jurisdictions these terms and definitions used herein may be given different names but relate to the same respective systems.

Embodiments of the present invention involve energy (e.g. electricity) demand and price forecasting to provide electricity market participants with artificial intelligence-based systems that allow for effectively implementing cost-saving, profit maximizing and energy efficient behaviours. Embodiments of the present invention may combine cloud-hosting, domain expertise, and machine learned modeling through scalable practices to create software as a service to both generators and consumers.

The present invention will allow commercial and industrial (“C&I”) entities (e.g. Manufacturing plants, data centers, healthcare facilities, business complexes, college campuses, etc.) to accurately estimate when system electrical load peaks are likely to occur and minimize their consumption to avoid these excess charges during peak hours. In addition, energy system or energy grid operators could more accurately estimate the occurrence peak demand and develop programs to incentivize consumers to minimize their load during these hours, thereby avoid setting new peak with load growth. This way, system operators could differ the need to build new electrical infrastructure as well as purchase additional electricity to support new peak demand levels. In addition, municipalities would have better insights and estimate of electrical loads, allowing them to save on avoidable costs in prepositioning generation assets.

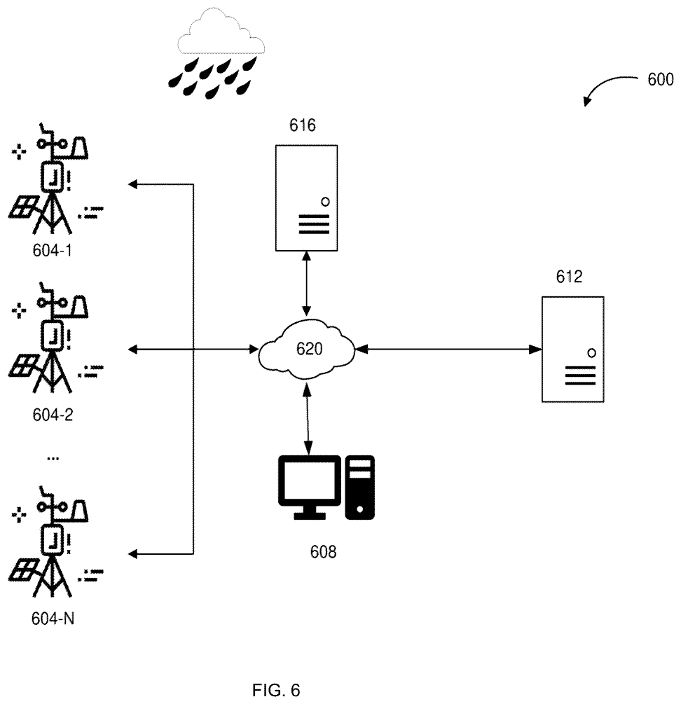

A person skilled in the relevant art will understand weather instruments or instrumentation, such as those referred to in FIG. 6 as weather instruments 604 (also referred to herein as weather stations 604), to refer to instruments and equipment for measuring atmospheric conditions typically used to provide information for weather forecasts and to study the weather and climate. The measurements taken may include, among others, temperature, atmospheric pressure, humidity, wind speed, wind direction, and precipitation amounts. Automated measurements may be taken on a regular cycle. Typically, such instrumentation is directed to the following: (a) Thermometer for measuring air and sea surface temperature; (b) Barometer for measuring atmospheric pressure; (c) Hygrometer for measuring humidity; (d) Anemometer for measuring wind speed; (e) Pyranometer for measuring solar radiation; (f) Rain gauge for measuring liquid precipitation over a set period of time; and (g) wind vane or wind sock for measuring general wind speed and wind direction. As used herein, it will be understood that “load sensitive weather equipment” or “load sensitive weather instrumentation” refers to weather equipment that is located in areas that are sensitive to fluctuations in energy load or are predictive thereof based on weather conditions. Such locations are typically areas of high energy (e.g. electricity) consumption (e.g. high load) that is largely dictated by weather conditions.

Preferred embodiments of load sensitive weather instrumentation include the following. To properly site wind speed and direction, clear, open, and level terrain at a distance at least ten times the height of any nearby buildings, trees, or other obstructions is recommended. In urban environments this is typically challenging, however, worth note that data collected from instrumentation failing these criteria can be severely impacted by localized roughness potentially impacting measurement over 25%. Three (3) meters is an optional height for Mesoscale monitoring efforts. Such towers require to be guyed to stable mounting blocks. For typical installations, clear land siting with no nearby obstructions is required. A radius of 5 meters about the tower is required for setting guy wires. A fiberglass enclosure is required to house electrical components including modem, data acquisition, power distribution, and other weather sensitive equipment and hardware.

In a preferred embodiment, the RX3000 remote station provides access to data through a sim enabled integrated modem and HOBOlink cloud access. The system connects to compatible equipment and allows for added voltage based modular data as well.

In a preferred embodiment, the ONSET 0.2 mm smart rainfall sensor is a tipping bucket rain gauge with a 0.2 mm resolution and operational temperature range of 0° C. to 50° C. and is used internationally. In another preferred embodiment, alternative precipitation, such as snow, hail, etc. may be measured using the RM Young 52202, a thermostat-controlled, electrically heated, tipping bucket rain gauge used to measure rain, snow, and other frozen precipitation. Its catchment area of 200 cm² and measurement resolution of 0.1 mm meet the recommendations of the World Meteorological Organization (“WMO”). This monitor is rugged and economical though due to the heater requirement in the winter does require a larger amount of energy. The operating range of this sensor is −20° C. to 50° C. and requires 18 W to operate the heater unit.

In a preferred embodiment, barometric pressure may be measured by the ONSET Barometric Pressure sensor, having a measurement range of 660 mb to 1070 mb and operational temp of −40 to 70 deg C. with +/−5 mbar accuracy.

In a preferred embodiment, temperature and relative humidity may be measured by the Onser 12-bit Temperature/Relative Humidity Smart Sensor having a temperature range of −40 to 75 degrees C. with an RH range from 0 to 100%—though error increases below −20 degrees C. and 10% RH or above 90% RH.

In a preferred embodiment, wind speed and direction may be measured by the HOBO Ultrasonic Wind Speed and Direction Smart Sensor. Resolution of 0.4 m/s and powered by its own built-in solar panel. Icing may occur below 15 degrees C.

In a preferred embodiment, solar irradiance may be measured by the HOBO silicon smart pyranometer. This product offers a measurement range of 0 to 1280 W/m2 over a spectral range of 300 to 1100 nm with +/−10 W/m2 at ambient temperature.

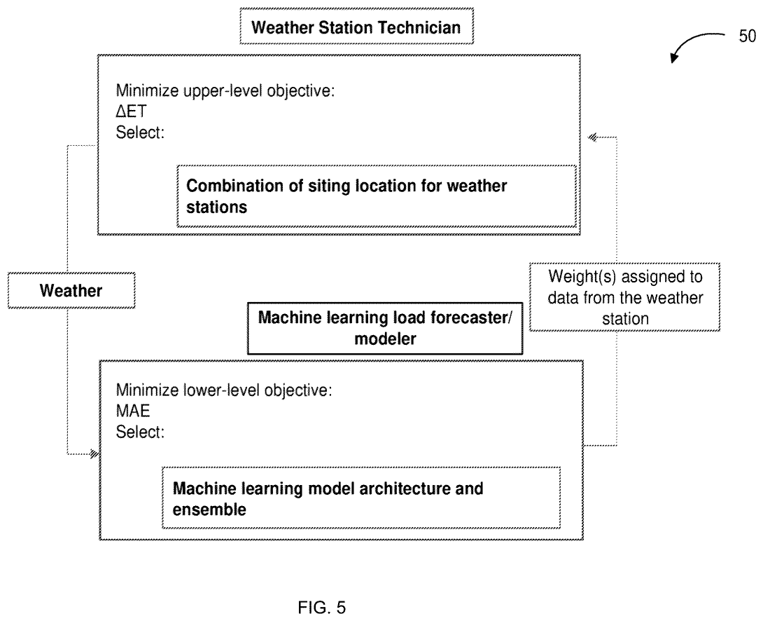

In a preferred embodiment, there is provided a process for the selection of suitable locations for the weather instrument. This can be determined through a bilevel optimization process. The process of siting “load sensitive” weather instruments (load sensitive locations) and determining the optimal hybrid machine learning (ML) model design for the load forecasting problem is characterized as a hierarchical decision-making optimization model for the coupled objectives. The optimization model is formulated as a bi-level optimization problem for a coupled siting of selected weather instruments and a design of a hybrid/ensemble of machine learning model task. The upper-level problem acting as a “leader” represent the interest of the weather station technician to properly site these stations to provide high quality data in a consistent and reliable manner with maximum access to the equipment and minimum obstruction to the variable being estimated. On the other hand, the lower-level problem acting as a “follower” represent the interest of the machine learning load forecaster to develop an ensemble of ML models that minimizes the load forecasting error (i.e., MAE). Each level controls its decision variables independently as shown in FIG. 5 in embodiment 50. The upper-level weather technician receives candidate locations of weather stations and total number of weather stations (usually less than the number of candidate locations) to be installed as input variables. He then selects a combination of sites from the candidate locations to install the weather stations, seeking to minimize the difference in evapotranspiration (ETi) between weather data from the installed instruments and reference theoretical evapotranspiration (ET0). It then passes weather data from these installed instruments to the lower-level machine learning modeling problem. The lower-level problem then selects machine learning model architecture and ensemble that seeks to minimize the mean absolute error (“MAE”) of the predictions made. The weights assigned to weather data from each weather station is passed back to the upper-level problem. The upper level/leader observing the lower-level selection, optimizes its choice of candidate location and passes it back to the lower-level problem. This process is repeated until an equilibrium is found where neither level has an incentive to change their selection. In a preferred embodiment, a network of load sensitive weather equipment, shown in FIG. 5 as monitoring points for weather conditions data, may be included throughout the grid in accordance with the manner described herein, which may be connected by a communication network. The entire grid and load sensitive weather equipment may be monitored by monitoring and control systems. In one embodiment, the load sensitive weather equipment may further comprise software programs, communication gateways, metering, and digital protection devices.

Although the present specification describes components and functions implemented in the embodiments with reference to standards and protocols known to a person skilled in the art, the present disclosure as well as the embodiments of the present invention are not limited to any specific standard or protocol. Each of the standards for Internet and other forms of computer network transmission (e.g., TCP/IP, UDP/IP, HTML, HTTP, SSL and SFTP) represent examples of the state of the art. Such standards are periodically superseded by faster or more efficient equivalents having essentially the same functions. Accordingly, replacement standards and protocols having the same functions are considered equivalents.

Preferred embodiments of the present invention can be implemented in numerous configurations depending on implementation choices based upon the principles described herein. Various specific aspects are disclosed, which are illustrative embodiments not to be construed as limiting the scope of the disclosure. Although the present specification describes components and functions implemented in the embodiments with reference to standards and protocols known to a person skilled in the art, the present disclosures as well as the embodiments of the present invention are not limited to any specific standard or protocol.

Some portion of the detailed descriptions that follow are presented in terms of procedures, steps, logic block, processing, and other symbolic representations of operations on data bits that can be performed on computer memory. These descriptions and representations are the means used by those skilled in the data processing arts to most effectively convey the substance of their work to others skilled in the art. A procedure, computer executed step, logic block, process, etc. may be here, and generally, conceived to be a self-consistent sequence of operations or instructions leading to a desired result. The operations are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers or the like.

A person skilled in the art will understand that the present description will reference terminology from the field of artificial intelligence, including machine learning, and may be known to such a person skilled in the relevant art. A person skilled in the relevant art will also understand that artificial neural networks generally refer to computing or computer systems that are design to mimic biological neural networks (e.g. animal brains). Such systems “learn” to perform tasks by considering examples, generally being programmed with or without task-specific rules. A person skilled in the relevant art will understand that convolutional neural networks, recurrent neural networks, transformer neural networks are classes of neural networks that specializes in processing data that has a sequential-like topology, such as energy markets.

Machine learning techniques will generally be understood as being used to identify and classify specific reviewed data. Machine learning approaches first tend to involve what is known in the art as a “training”, “validation” or “testing” phase. In the context of classifying functions, a training “corpus” is first constructed. This corpus typically comprises a set of known data; in the case of the present invention, training data may, in a preferred embodiment, comprise historic weather data and corresponding energy or grid “loads” for specific time intervals. Each set of data is optionally accompanied with a “label” of its disposition. It is preferable to have fewer unknown samples within the test or training data. Furthermore, it is preferable for the corpus to be representative of the real-world scenarios in which the machine learning techniques will ultimately be applied. This is followed by the training or testing in which the data together with the labels associated with the data, files, etc. themselves, are fed into an algorithm that implements the “training phase”. An aspect of the training can be to remove dataset bias. Dataset bias in machine learning is a type of error in which certain elements of a dataset are more heavily weighted and/or represented than others. A biased dataset does not accurately represent a model's use case, resulting in skewed outcomes, low accuracy levels, and analytical errors. Another aspect of the training is to remove variance, namely errors from sensitivity to small fluctuations in the training set. High variance can cause an algorithm to model the random noise in the training data, rather than the intended outputs. The goal of this phase is to automatically derive a low bias, low variance “generative model”. A person skilled in the relevant art will understand that a generative model effectively encodes a mathematical function whose input is the data and whose output is also the data. By exploiting patterns that exist in the data (pattern data) identified through one or more training phases, the model can learn the processes that generates similar patterns when applied to previously unseen or new data sets. A generative machine learning algorithm should ideally produce a generator that is reasonably consistent with the training examples and that has a reasonable likelihood of generating new instances that are similar to its training data but not identical. Specific generative machine learning algorithms in the art include the Autoregressive Recurrent Neural Networks, Variational Auto-Encoders, Generative Adversarial Neural Networks, Energy-Based Models, Flow-Based Neural Networks, and others known in the art. The term generator is also used to describe a model. For example, one may refer to a Recurrent Neural Network Generator. Once the model/generator is established, it can be used to generate new instances, scenarios or data sets that are presented to a computer or computer network in practice. Model generator can be portions or components of a commercially available software tool for predicting outcomes using a neural network model. One such software tool that has been found to be suitable is NEURALWORKS PREDICT, which is produced by Neuralware of Carnegie, Pa. A person skilled in the art will understand that the present invention is not limited to using any particular software, and that persons skilled in the art to which the invention relates will readily be capable of providing suitable neural network software in view of the teachings herein. As well understood in the art, a neural network is a non-linear estimation technique that replicates the function on neurons in the human brain through a collection of interconnected mathematical functions with dynamic weighting of connections enabling continuous “learning”. Neural networks form these interconnected mathematical functions from the input pattern, not the input data, and apply continuously changing weights in response to the level of correlation. As a result, neural network models are able to extract the essential characteristics from numerical data as opposed to memorizing all of the data. This reduces the amount of data needed and forms an implicit model without having to form a complex physical model of the underlying phenomenon such as in the case of a building. The NEURALWORKS PREDICT package is specifically directed to the use of a neural network to predict outcomes for any of a wide range of problems. PREDICT can be used by software developers who have no expert knowledge of neural networks. With only minimal user involvement, PREDICT addresses the issues associated with building models from empirical data. PREDICT analyzes input data to identify appropriate transforms, partitions the input data into training, validation and test sets, selects relevant input variables, and then constructs, trains, and optimizes a neural network tailored to the problem. As persons skilled in the art to which the invention relates will readily be capable of employing PREDICT or a similar commercially available software tool as described herein, or of otherwise providing suitable neural network software elements, neural network details will not be described herein for purposes of clarity.

In alternative embodiments, instead of (or in addition to) neural network or machine learning software tool, a system may be adapted to include a different artificial intelligence software tool. For example, the artificial intelligence software tool may include an adaptive system other than a neural network software tool. Suitable artificial intelligence software, including its design, algorithms, models, and processes, may include artificial intelligence using relational database management techniques, web-enabled data capturing, visual monitoring, statistical reporting, and remote monitoring software tools. Such artificial intelligence software's capabilities may include but are not limited to artificial, non-linear, statistical data-modeling tools, pattern matching and learning capabilities, recognizing locations of facilities, tuned weather data, energy usage, and statistical correlation. A person skilled in the relevant art will understand “tuned” weather data or forecast data to refer to the best match to both historic and current conditions as measured by instrumentation at each location. A person skilled in the art will also recognize that “tuned” weather data references weather data from weather stations 604 in their optimized location, after training model 820 has been verified to have a mean absolute error within tolerance, and said training model 820 has been deployed. Persons of ordinary skill in the art will be able to readily select and configure such artificial intelligence software for use in projecting energy load based on inputted actual and current weather condition data.

The present invention may be a system, a method, and/or a computer program product such that selected embodiments include software that performs certain tasks. The software discussed herein may include script, batch, or other executable files. The software may be stored on a machine-readable or computer-readable storage medium and is otherwise available to direct the operation of the computer system as described herein and claimed below. In one embodiment, the software uses a local or database memory to implement the data transformation and data structures so as to automatically generate and add libraries to a library knowledge base for use in detecting library substitution opportunities, thereby improving the quality and robustness of software and educating developers about library opportunities and implementation to generate more readable, reliable, smaller, and robust code with less effort. The local or database memory used for storing firmware or hardware modules in accordance with an embodiment of the invention may also include a semiconductor-based memory, which may be permanently, removably or remotely coupled to a microprocessor system. Other new and various types of computer-readable storage media may be used to store the modules discussed herein. Additionally, those skilled in the art will recognize that the separation of functionality into modules is for illustrative purposes. Alternative embodiments may merge the functionality of multiple software modules into a single module or may impose an alternate decomposition of functionality of modules. For example, a software module for calling sub-modules may be decomposed so that each sub-module performs its function and passes control directly to another sub-module.

In addition, selected aspects of the present invention may take the form of an entirely hardware embodiment, an entirely software embodiment (including firmware, resident software, micro-code, etc.), or an embodiment combining software and/or hardware aspects that may all generally be referred to herein as a “circuit,” “module” or “system.” Furthermore, aspects of the present invention may take the form of computer program product embodied in a computer readable storage medium or media having computer readable program instructions thereon for causing a processor to carry out aspects of the present invention. Thus embodied, the disclosed system, a method, and/or a computer program product is operative to improve the design, functionality and performance of software programs by adding libraries for use in automatically detecting and recommending library function substitutions for replacing validated code snippets in the software program.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a dynamic or static random access memory (RAM), a read-only memory (ROM), an erasable programmable read-only memory (EPROM or Flash memory), a magnetic storage device, a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

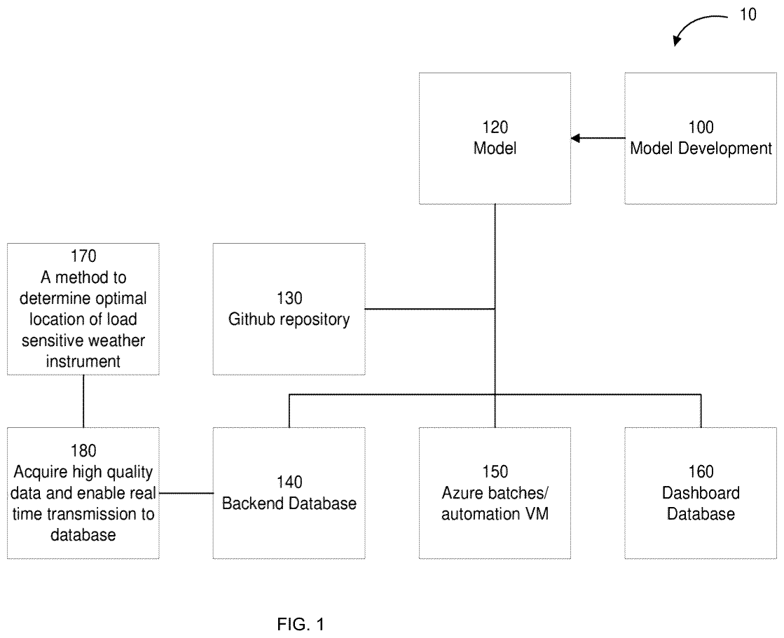

A person skilled in the relevant art will understand that the computer readable program instructions described herein can be downloaded to respective computing/processing devices from a computer readable storage medium or to an external computer or external storage device via a network, for example, the Internet, a Public Switched Circuit Network (PSTN), a packet-based network, a personal area network (PAN), a local area network (LAN), a wide area network (WAN), a wireless network, or any suitable combination thereof. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Java, Python, Visual Basic.net, Ruby, Smalltalk, C++ or the like, and conventional procedural programming languages, such as the “C” programming language, Hypertext Precursor (PHP), or similar programming languages. The computer readable program instructions may execute entirely on the user's computer, partly on the user's computer, as a stand-alone software package, partly on the user's computer and partly on a remote computer or entirely on the remote computer or server or cluster of servers. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention. A person skilled in the relevant art will understand that the AI based or algorithmic processes of the present invention may be implemented in any desired source code language, such as Python, Java, and other programming languages and may reside in private software repositories or online hosting service such as GitHub (see for example 130 in FIG. 1).

A person skilled in the relevant art will understand that the term “deep learning” refers to a type of machine learning based on artificial neural networks. Deep learning is a class of machine learning algorithms (e.g. a set of instructions, typically to solve a class of problems or perform a computation) that use multiple layers to progressively extract higher level features from raw input. For example, in image processing, lower layers may identify edges, while higher layers may identify human-meaningful items such as digits or letters or faces.

A person skilled in the art will understand that the operation of the network ready device (e.g. mobile device, workstation, etc.) may be controlled by a variety of different program modules. Examples of program modules are routines, programs, objects, components, data structures, etc. that perform particular tasks or implement particular abstract data types. It will be understood that the present invention may also be practiced with other computer system configurations, including multiprocessor systems, microprocessor-based or programmable consumer electronics, network PCS, minicomputers, mainframe computers, and the like. Furthermore, the invention may also be practiced in distributed computing environments where tasks are performed by remote processing devices that are linked through a communications network. In a distributed computing environment, program modules may be located in both local and remote memory storage devices. One skilled in the relevant art would appreciate that the device connections mentioned herein are for illustration purposes only and that any number of possible configurations and selection of peripheral devices could be coupled to the computer system.

Embodiments of the present invention can be implemented by a software program for processing data through a computer system. It will be understood by a person skilled in the relevant art that the computer system can be a personal computer, mobile device, notebook computer, server computer, mainframe, networked computer (e.g., router), workstation, and the like. The program or its corresponding hardware implementation is operable for providing user authentication. In one embodiment, the computer system includes a processor coupled to a bus and memory storage coupled to the bus. The memory storage can be volatile or non-volatile (i.e. transitory or non-transitory) and can include removable storage media. The computer can also include a display, provision for data input and output, etc. as will be understood by a person skilled in the relevant art.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “receiving,” “creating,” “providing,” or the like refer to the actions and processes of a computer system, or similar electronic computing device, including an embedded system, that manipulates and transfers data represented as physical (electronic) quantities within the computer system's registers and memories into other data similarly represented as physical quantities within the computer system memories or registers or other such information storage, transmission or display devices.

While aspects of this application are primarily discussed as a method, a person of ordinary skill in the art will understand that the apparatus discussed above with reference to a data processing system may be programmed to enable the practice of the method of the application. Moreover, an article of manufacture for use with a data processing system, such as a pre-recorded storage device or other similar computer readable medium or computer program product including program instructions recorded thereon, may direct the data processing system to facilitate the practice of the method of the application. It is understood that such apparatus, products, and articles of manufacture also come within the scope of the application.

A user can interact with system of the present invention through a user interface in a conventional manner. User interface can comprise, for example, a graphical user interface (GUI) that operates in accordance with standard windowing and graphical user interface protocols supported by MICROSOFT WINDOWS or similar operating system. That is, the user can manipulate (e.g., open, close, resize, minimize, etc.) windows on display a, launch application software that executes within one or more windows, and interact with pictures, icons and graphical control structures (e.g., buttons, checkboxes, pull-down menus, etc.) on display using mouse, keyboard or other input devices. What is displayed within a window under control of an application program is generally referred to herein as a screen, screen display or “dashboard” of the application program. Such user interfaces can include not only the logic through which screen displays are generated and made viewable but also computational logic that generates and organizes, tabulates, etc., numerical values to be displayed or otherwise output. Similarly, user interfaces can include logic for importing, exporting, opening and closing data files.

In particular, the sequences of instructions which when executed cause the method described herein to be performed by the data processing system may be contained in a data carrier product according to one embodiment of the application. This data carrier product may be loaded into and run by the data processing system. In addition, the sequences of instructions which when executed cause the method described herein to be performed by the data processing system may be contained in a computer software product or computer program product (e.g., comprising a non-transitory medium) according to one embodiment of the application. This computer software product or computer program product may be loaded into and run by the data processing system. Moreover, the sequences of instructions which when executed cause the method described herein to be performed by the data processing system may be contained in an integrated circuit product (e.g., a hardware module or modules) which may include a coprocessor or memory according to one embodiment of the application. This integrated circuit product may be installed in the data processing system.

As provided in FIG. 1 in embodiment 10, there is provided a method 170 to determine the optimal location of load sensitive weather equipment. This is based on load (e.g. historical data) and a demand model of energy consumption. Traditionally, and for weather forecasting, weather equipment only need to be placed in a few locations. Typically, this means that equipment is provided at airports, coastal locations, outskirt of cities to avoid obstructions, and the like. In the present invention, the weather instrumentation must be provided at specific “load sensitive” locations, hence the process for locating such “load sensitive” weather instrumentation. The location of the load sensitive weather equipment allows for the acquisition of high quality (e.g. highly correlative with energy use) data and enables real time transmission of that data to the database (e.g. 140 in FIG. 1).

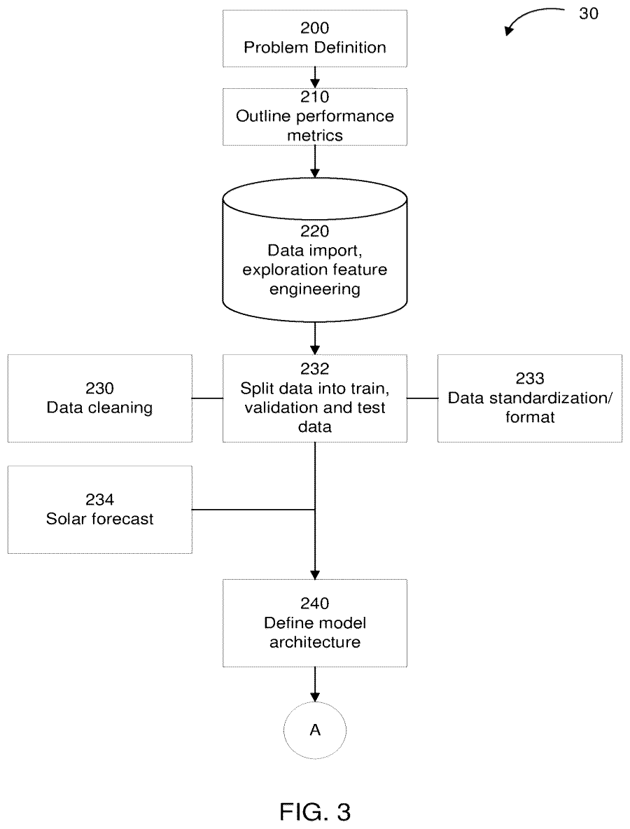

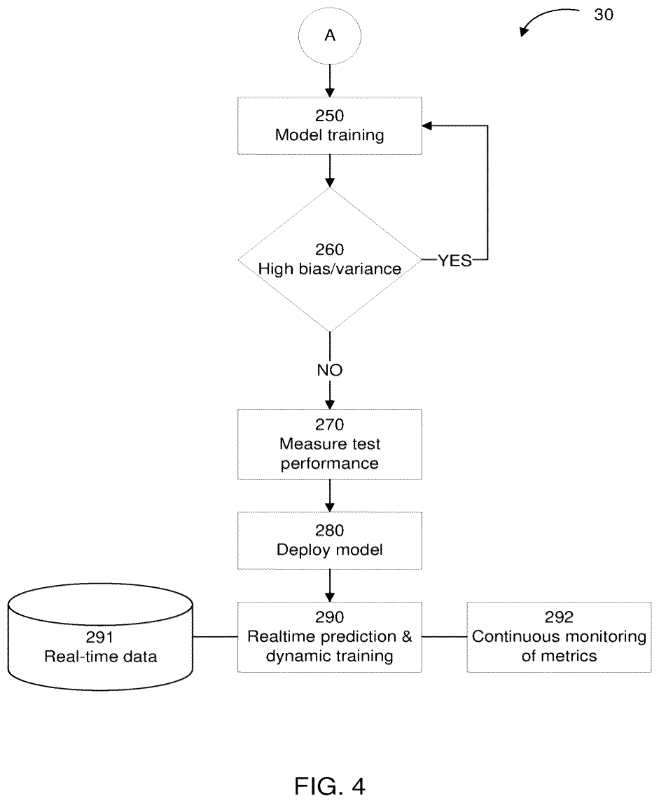

In FIG. 1, there is also provided, as a preferred embodiment, a predictive artificial intelligence or neural network model development process 100 (described in greater detail when referencing FIGS. 3 and 4) for implementing an energy use prediction or predictive model 120. The artificial intelligence/artificial intelligence-based module of the present invention will use correlations between several factors (including but not limited to weather conditions, historical load data, day of the week, holidays, behind the meter renewable generation, electricity prices) to forecast the energy/electrical load within a grid using multiple variables, but preferably weather. In a preferred embodiment, weather can be the main predictor of energy load within the grid. As shown in FIG. 1, the model development process leads to the creation of an A.I. predictive model 120, which may be stored in a repository (such as GITHUB as shown in 130 of FIG. 1). Once the model 120 has been generated (see below in FIGS. 3 and 4), it can be used to predict or estimate the grid load (e.g. energy that will be consumed by those on the grid). Because the neural network model was generated based upon training data e.g. historical weather data and energy load data), then in response to the actual weather conditions as determined by the load sensitive weather instrumentation, the neural network model outputs an estimate of the energy load that would have been needed during the applicable time interval.

The model 120 may also interact with a backend database 140 which may be then batched processed 150 (e.g. preferably using AZURE™), which can then be outputted to a dashboard database 160 for ultimate display in a user-friendly dashboard. The backend database 140 may contain historical energy load data, day of the week/day of the week data, holidays/holiday data, behind the meter renewable generation (renewable energy generation data), electricity prices to obtain high quality weather data which can then be transmitted (e.g. preferably in real time) (see 180 in FIG. 1) after the weather instrumentation (e.g. load sensitive weather instrumentation) has been optimally placed in the appropriate location (see method 170 of FIG. 1).

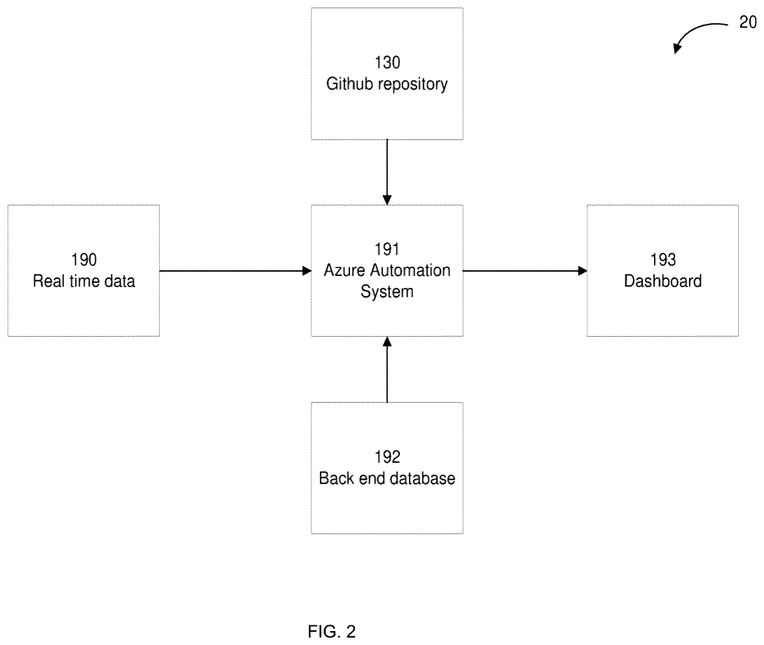

An alternative embodiment is provided in FIG. 2 in embodiment 20. In this example, real time data from the weather instrumentation 190 may be piped directly into the batch process step 191 along with back end data 192 to be feed directly to dashboard 193.

The model of the present invention generates a neural network-based model 100 (see FIG. 1) in response to training data based on tuned weather or forecast data and historical grid load condition data. As described herein, model 100 can be used as a tool for projecting or estimating the energy load that is predicted for a given area for a given time interval. In order to generate model 100, parameters for the neural network algorithm must be defined that are appropriate for the application. These parameters include the data variability or noise level, data transformation scope, variable selection scope, and network selection scope. The last three parameters refer to the scope or the range of options the algorithm evaluates in finding the best distributions of data, data subsets of variables and network types such as Multi-Layer Perception (MLP) and Generalized Regression (GR). Persons skilled in the art to which the invention relates will readily be capable of defining suitable parameters for neural network tool or other such neural network element. Commercially available neural network prediction software, such as NEURALWORKS PREDICT, typically automates or assists with parameter selection and other such setup tasks.

Referring to FIG. 6, an alternative embodiment, system 600, of the system for electrical load forecasting is provided. System 600 includes weather stations 604-1, 604-2 . . . 604-N. (Weather stations are referred to here generically as weather station 604 and collectively as weather stations 604. The nomenclature is used elsewhere herein.) At least one weather station 604 is connected to a processing server 612 via a network 620, where weather data (also referred to herein as weather sensor data or sensor data) may be fathered at weather stations 604, and processing server 612 may request and receive said weather data through network 620. System 600 further includes external databases 616 which may include multiple data sources and multiple data types, including data pertaining to electrical load over a period of time for a geographical area, data pertaining to electrical load generated by renewable energy sources within the geographical area and electrical price data. Other examples of data sources and data types will be provided further below. Said data may be requested and received by processing server 612 via network 620. System 600 further includes client device 608 for a user to interact with processing server 612. As such, weather stations 604, processing server 612, external databases 616 and client device 608 are all interconnected via network 620.

Processing server 612, external databases 616 and client devices 608 may be implemented with computer systems which are well known in the art. Generally speaking, computers include a central processor, system memory, and a system bus that couples various system components (typically provided on cards), including the system memory, to the central processor. A system bus may be any of several types of bus structures including a memory bus or memory controller, a peripheral bus, and a local bus using any of a variety of bus architectures. The structure of a system memory may be well known to those skilled in the art and may include a basic input/output system (BIOS) stored in a read only memory (ROM) and one or more program modules such as operating systems, application programs and program data stored in random access memory (RAM). Computers may also include a variety of interface units and drives for reading and writing data. A user can interact with computer with a variety of input devices, all of which are known to a person skilled in the relevant art. Computers can operate in a networked environment using logical connections to one or more remote computers or other devices, such as a server, a router, a network personal computer, a peer device or other common network node, a wireless telephone or wireless personal digital assistant.

As previously described, weather stations 604 may include a variety of sensors to measure the surrounding environment, including, but not limited to the following: (a) Thermometer for measuring air and sea surface temperature; (b) Barometer for measuring atmospheric pressure; (c) Hygrometer for measuring humidity; (d) Anemometer for measuring wind speed; (e) Pyranometer for measuring solar radiation; (f) Rain gauge for measuring liquid precipitation over a set period of time; and (g) wind vane or wind sock for measuring general wind speed and wind direction. A person skilled in the art will recognize the different potential sensors that can be included in weather station 604. Weather sensor data that is received from weather stations 604 includes readings from all of the abovementioned sensors, including or excluding any other sensors that may be in weather station 604. Weather sensor data may be measured at predetermined intervals and stored to be sent or retrieved by processing server 612, or may be measured at frequent intervals to be stored, where it may be queried and retrieved by processing server 612. As previously stated, the location and placement of weather stations 604 is important, and will be described below.

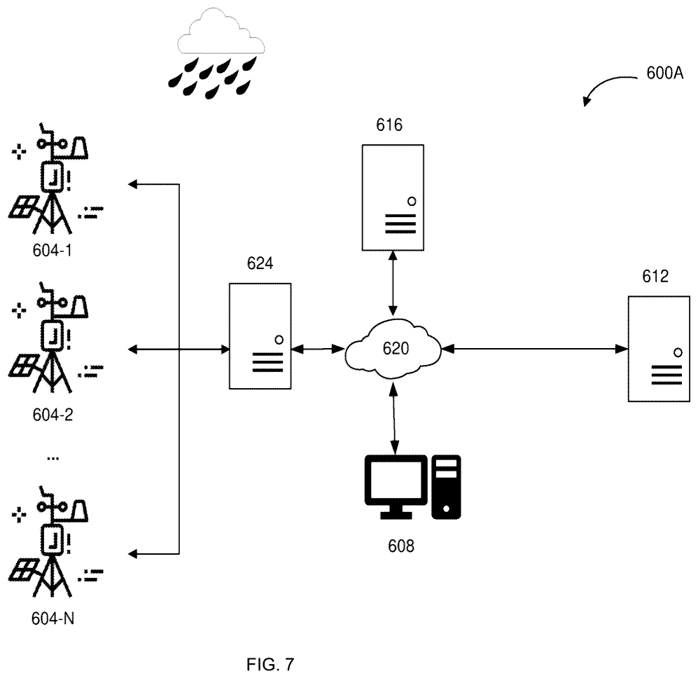

As the sensors in weather station 604 collect weather data, the weather data may be sent to processing server 612. In alternate embodiments, weather data may be aggregated and logged in an intermediate server 624 (shown in FIG. 7) before being sent to processing server 612. In an embodiment where intermediate server 624 is present, intermediate server 624 may log the weather sensor data from weather stations 604, the time stamp of the weather sensor data, and the location of weather station 604 from which the weather sensor data was received. Weather data may be requested by processing server 612 and then received either from weather stations 604 directly through network 620, as shown in FIG. 6, or weather sensor data may be requested and then received through intermediate server 624, as shown in FIG. 7. Requesting weather data may also be done through queries. Alternatively weather data from weather station 604 maybe sent/transmitted directly to processing server 612 via network 620 at regular predetermined intervals. Said predetermined intervals may line up with the same predetermined intervals that measurements are taken by the various sensors of weather station 604. A person skilled in the art will recognize the different methods of getting data from weather station 604 to processing server 612 to be processed and used.

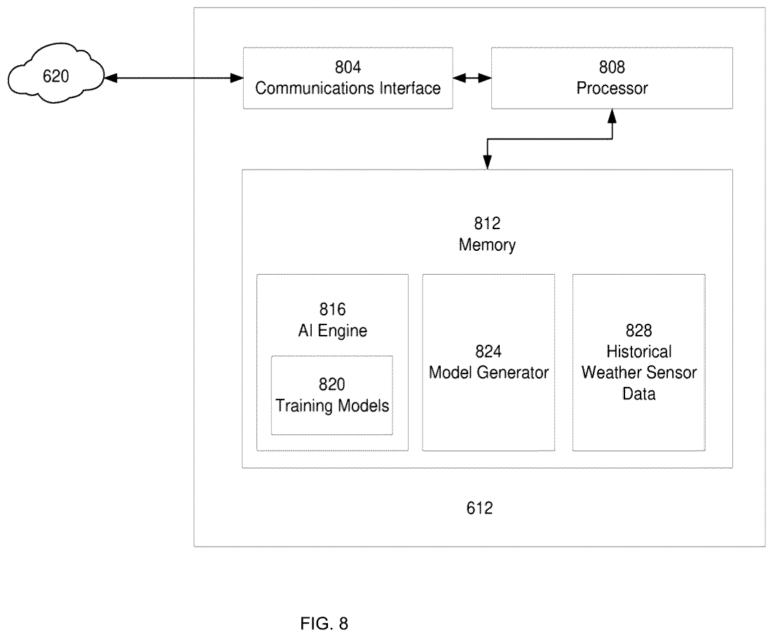

Referring to FIG. 8, an embodiment of processing server 612 is shown. Processing server 612 may include a processor 808 interconnecting a memory 812 and a communications interface 804. Processor 808 can include a central-processing unit (CPU), a microcontroller, a microprocessor, a processing core, a field-programmable gate array (FPGA), or similar. Processor 808 may include multiple cooperating processors. Processor 808 can cooperate with non-transitory computer readable medium, such as memory 812 to execute instructions to realize the functionality discussed herein.

As shown in FIG. 8, memory 812 can include a combination of volatile (e.g. Random Access Memory or RAM) and non-volatile memory (e.g. non-volatile random-access memory, read only memory or ROM, electrically erasable programmable read only memory or EEPROM, flash memory). All or some of memory 812 may be integrated with processor 808. Memory 812 stores computer readable instructions for execution by processor 808.

In particular, memory 812 stores a plurality of computer-readable data and programming instructions, accessible by processor 808, in the form of software objects, such as various applications, queries or types of data for use during the execution of those applications. In particular, the execution of the instructions in memory 812 by processor 808 allow for the creation of training models 820 using model generator 824. Furthermore, the execution of the instructions in memory 812 by processor 808 allow an AI engine 816 (also referred to herein as predictive engine 816, machine learning engine 816 or load prediction engine 816) to use training model 820 to predict/forecast electrical load data based on weather sensor data from weather stations 604. In addition, memory 812 may calculate the mean absolute error to determine the accuracy of the predicted electrical load data in comparison to current actual electrical load data. This will be further discussed below. A person skilled in the art will now recognize that various forms of computer-readable programming instructions stored in memory 812 can be executed by processor 808 as applications or as queries.

As shown in FIG. 8, memory 812 includes AI engine 816, model generator 824 and historical weather sensor data 828. Model generator 824 may produce training models 820, to be used by AI engine 816. Training models 820 may be created based on weather data from weather stations 604 and electrical load data. Training models 820 may be further enhanced for accuracy with additional data and variables that may affect either the accuracy of the weather data, or affect the accuracy of the electrical load data. For example, electrical load data may need to be manipulated prior to being used to create training model 820. In another example, renewable energy data may be added to training model 820 to account for additional sources of power generation. Once training model 820 has been created and tested for accuracy, it may be used by AI engine 816 to predict electrical loads based on weather data.

In the current embodiment, AI engine 816 may use a single training model 820 to predict electrical load data. In alternate embodiments, AI engine 816 may use different training models 820 depending on the situation and the needs. In alternate embodiments, there may be multiple AI engines 816 using different training models 820. It will occur to a person skilled in the art the various configurations of AI engines 816 and training models 820 for processing server 612 to predict electrical load data based on weather data from weather stations 604. The normal operation of AI engine 816, and the dynamic training of AI engine 816 will be further described below.

Memory 812 further includes historical weather sensor data 828. Historical weather sensor data 828 may be a database of logs to be used for training and comparison purposes. This will be further described below.

In addition, as shown in FIG. 8, processing server 612 further includes communications interface 804. Communications interface 804 allows for processor 808 to communicate with network 620. Communications interface 804 includes suitable hardware (e.g. transmitters, receivers, network interface controllers and the like) allowing processing server 612 to communication with other components in system 600, such as external databases 616 and weather stations 604. The specific components of communications interface 804 may be selected based on the type of network or other links that processing server 612 may be required to communicate over.

Processing server 612 can also include input devices that connect to processor 808, such as a keyboard and mouse, as well as output devices, such as a display. Alternatively, or in addition, the input and output devices can be connected to processor 808 via communications interface 804 or via another computer device. In other words, input and output devices can be local to processing server 612 or remote. In the present embodiment, weather stations 604 may be an example of input devices connected to processor 808 in processing server 612 via communications interface 804. As previously indicated, weather stations 604 may provide weather data to processing server 612 in order to provide predicted electrical load data for a specific geographic area. While in the current embodiment, weather stations 604 are connected to processing server 612 through network 620, in other embodiments, weather stations 604 may be operatively connected/connected directly to processing server 612 through communications interface 804. A person skilled in the art will now recognize the availability of different input and output devices and that there are a variety of methods of connecting to processor 808. In addition, a person skilled in the art will further recognize the availability of weather stations 604 and the different methods of providing processing server 612 with weather sensor data.

Processing server 612, in its preferred configuration is a server, however, processing server 612 may be any computer device such as, but not limited to, a desktop computer, a laptop computer, another server, a kiosk, a cell phone, a tablet, a mobile device, a monitor or other suitable device. A person skilled in the art will also appreciate that other, different configurations of processing server 612 are contemplated. For example, processing server 612 may combined with a single weather station 604 as a single unit, while other weather stations 604 may be providing their data wirelessly over network 620 to processing server 612.

Returning to FIG. 6, system 600 includes external databases 616. External databases 616 provide additional data for processing server 612 to draw upon. For example external databases 616 may include the current electrical load data for a geographic location. In alternative embodiments, external databases 616 may include more than one external source. For example, external databases 616 may include both the current electrical load data for a given geographical area and also energy generation capabilities and data for renewable sources within the same geographical area. Data retrieved from external databases 616 may not be homogeneous. More specifically, the data may come from different sources, and may also be of different types, represent different functions, and be of different units. Other data that may be provided by external databases 616 include, but is not limited to, electrical generation capabilities of local generators, load data pertaining to the use of electrical power by certain industries, historical weather data of a geographic location, and historical electrical load data for a geographic location. A person skilled in the art will understand the various sources of data that maybe used in external databases 616, and the potential types of data that may be provided for use in processing server 612.

System 600 may further include client devices 608. Client devices 608 may act as both input and output interface for users to view the processing of processing server 612, or provide user input and display output from processing server 612. Similar to that of processing server 612, client devices 608 may include similar components with similar features and functions, including a processor interconnecting a memory and a communications interface.

The memory of client device 608 may provide instructions to provide a front-end interface to allow users of varying roles to access processing server 612. Client devices 608 may be used for client users who wish to view the predicted electrical load data results for any given time in the future, or any given time frame in the future. A client user may also query and view any other data such as, weather sensor data from weather stations 604, and current electrical load data pulled from external databases 616. As such, client users using client devices 608 can view both the inputs into AI engine 816, and the outputs from AI engine 816.

Client devices 608 may also be used by administrator users who wish to adjust the training models 820, the operations of AI engine 816, or wish to generate a new model using model generator 824. Administrator users may also provide test data to AI engine 816 to verify the accuracy of the predictions provided by said AI engine 816. Administrative users may also use client devices 608 to monitor the outputs of AI engine 816 and to prevent any predicted load data that may not be accurate by virtue of a MAE outside the permitted tolerance from being sent back to AI engine 816 for training. The sending of predicted load data and weather data back to AI engine 816 for training will be discussed further below. It will occur to a person skilled in the art that an administrator user may monitor the operations of processing server 612 for errors or issues of accuracy of prediction from AI engine 816, and may also create new training models 820 using model generator 824. These two roles are not necessarily limited to administrator users but maybe divided into two separate types of users as well.

Client devices 608 may also include input devices, such as a keyboard and mouse, as well as output devices, such as a display. A person skilled in the art will now recognize the availability of different input and output devices available to connect to client device 608.

Client device 608 can be a computer device such as, but not limited to, a desktop computer, a laptop computer, another server, a kiosk, a cell phone, a tablet, a mobile device, a monitor or other suitable device. A person skilled in the art will also appreciate that other, different configurations of client device 608 are contemplated.

System 600 further includes network 620, which interconnects weather stations 604, external databases 616, client devices 608 and processing server 612. Network 620 is an example implementation of the connection between components in system 600, and a person skilled in the art will recognize that network 620 is not particularly limited in its configuration. Network 620 may be any form of network, including a wireless access network (WAN), local access network (LAN), or the Internet, and maybe accessed by said client devices 608 or processing server 612. Computers, such as processing server 612 and client devices 608 can operate in a networked environment using logical connections to one or more remote computers or other devices, such as a server, a router, a network personal computer, a peer device, a wireless telephone or wireless personal digital assistant. In the current embodiment, network 620 may be implemented over the Internet. The standards or protocols used for the network, as previously stated, may include any form of transmission. In addition, any desired levels and types of security and encryption protocols are contemplated and can be implemented over network 620. A person skilled in the art will recognize the different potential network types and different potential network configurations that may be used, along with the different standards and protocols of transmission within the network, and the different forms of security and encryption protocols available.

In a preferred embodiment, the model generating process provided in FIGS. 3 and 4 produces the model 120, in response to the training data along with other inputs. Model 120 represents load forecasting or prediction model for a given grid for a given time interval. As shown in FIG. 4 (see step 290), actual weather condition data may be inputted. The actual weather condition data represents weather conditions during the applicable time interval. At steps 290 to 292, model 120, in response to the actual weather condition data, produces a prediction or estimate of the grid load for a given grid and a given time interval. The prediction comprises a six day hourly grid load expressed in an array/table of 144 columns and streamed as a graph in the dashboard and may, in a preferable embodiment, be extendable to a fourteen day hourly forecasts.

FIGS. 3 and 4 shows a preferred embodiment of the present invention as embodiment 30. As seen in FIGS. 3 and 4, there is provided a method of training the artificial intelligence model 120 to be used in the system described above (see FIGS. 1 and 2). As can be seen in FIG. 3, there is provided a stage were the initial problem is defined (see 200 in FIG. 3). In a preferred embodiment, the problem would be defined as predicting or forecasting the grid load in view of weather conditions. Next is defined the necessary metrics for determining accuracy of the model (see 210 in FIG. 3). There are several standard metrics for determining accuracy, however, the appropriateness of the metrics used is dependent on the type of problem being solved (classification, regression, etc.). Herein, mean absolute error (MAE), mean absolute percentage error (MAPE) and root mean squared error (RMSE) are employed considering the problem being solved is a regression problem. MAE is considered most appropriate since it reflects a direct measure of the error in the variable being predicted and a small variation in electricity load during shoulder months could be costly. MAE is defined as a measure of errors between paired observations expressing the same phenomenon. It is expressed mathematically below (see EQN 1).

$$\\ \begin{matrix}MAE = \frac{{\sum }_{t}^{n} ( \vert {L}_{{y}_{t}} - {L}_{{x}_{t}} \vert )}{n} , & ( 1 )\end{matrix}$$

where Ly an Lx denote predicted an observed load respectively an n the total number of data points.
   Data importation (historical and current data sets), data exploration and feature engineering is shown in 220. It will be understood by a person skilled in the relevant art that data exploration is process of analyzing or examining to identify outliers, missing data, skewed distribution or an obvious trend in the data. As shown in 232 the data may be split into training, validation and test data. The data can also be subject to data cleaning (see 230) as well as standards data standardization and formatting (230 and 233, respectively).

Once the model architecture has been defined (see 240) and the data has been structured, the model training can be implemented (see 250 in FIG. 4) in an iterative process whereby the variance in the test data and the expected result can be determined through a series of iterations (e.g. hi bias/variance) until there is low bias and variance, reflected in the performance/accuracy metric of the model. Where there is little or no bias and/or variation, the model can move to a test performance (see 270 in FIG. 4) followed eventually by deployment model (see 280) in which time the real-time data can be interacting with the real-time prediction and dynamic training followed by continuous monitoring of the process (see 292).

In a preferred embodiment, there is also the ability to include a solar forecast (see 234 in FIG. 3), which allows the model to incorporate a predicted aspect of weather, such as the amount of sunlight, to be incorporated into the model. With the exponential growth of distributed small-scale renewable energy generation, the need for a technology to estimate and forecast the aggregate power production of these units is emerging. The output of such units offsets consumers' electricity demand, and thus impacts the power systems' net load. The solar forecasting method incorporated utilizes a small sample of input data to nowcast, which involves estimating the current total solar generation from a small sample (subset) of solar generation in a jurisdiction and forecasting aggregated power generation of large fleet of distributed behind the meter solar generation.

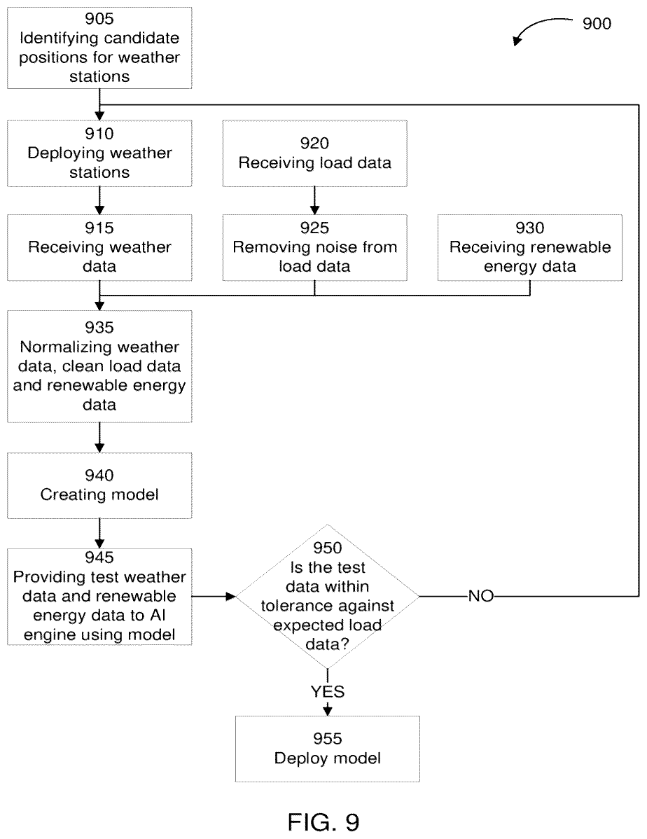

FIG. 9 shows an embodiment of method 900. Method 900 shows the process for creating training model 820 to be used by AI engine 816.

At block 905, candidate positions for weather stations 604 are located. As previously indicated above, this may be dependent on multiple factors, including both the environmental conditions surrounding the candidate positions and a proximity to the geographic location where electrical load data is to be predicted. Environmental conditions include, but are not limited to, ensuring that there are no surroundings that will affect the sensor readings for weather stations 604. For example, if weather station 604 is placed on the roof of a building for accurate readings on wind speed, and to avoid ambient temperature from an urban environment, an environmental condition that may affect its reading may include a tall building blocking wind from a certain direction. As such weather station 604 may not receive an accurate sensor reading for wind speed and wind direction from a specific direction. Proximity to the geographic location where electrical load data is to be predicted is also important, as if the placement of weather station 604 is too far from the target geographic location, then weather patterns may not be accurately reflected. For example, if weather station 604 was placed next to a body of water, and the target geographic location for the prediction of electrical load data is 500 km inland, and away from the body of water, then any weather data received from said weather stations 604 may have no effect on the electrical load of the target geographic location. A person skilled in the art will recognize the various factors and variables that need to be considered when identifying candidate positions for weather stations.

Once candidate positions for weather stations 604 have been identified, the weather stations 604 may then be deployed as depicted in block 910. Deployment of weather stations 604 includes providing power to said weather stations 604 and connecting them to network 620. Once deployed weather stations 604 may start measuring data with the sensors of weather stations 604 app predetermined intervals. The predetermined intervals may be a variable that is adjustable based on the specifications and needs of the client, or the needs of the geographic location. For example, if a high variation of electrical load data is expected, or if a high variation on weather data is to be expected, then a more frequent measurement of weather data by the sensors of weather stations 604 may be performed. A further example of a high variation of weather data may be locations that experience frequent fluctuations between rain and sunshine, whereas a low variation of weather data may be locations that receive stable weather patterns, such as a desert. A person skilled in the art will recognize the different configurations and intervals of gathering weather data from sensors of weather stations 604.

At block 915, weather data may be sent to processing server 612 via network 620. The interval at which weather data may be sent to processing server 612 maybe dependent on the predetermined intervals at which sensors of weather stations 604 gather weather data. For example, if weather station 604 gathers a temperature at a specific time, it may then subsequently push the temperature data to processing server 612. Alternatively, weather data may be queried or requested by processing server 612, and then sent to be received by processing server 612 via network 620. The query may be sent at predetermined intervals, that may be set manually depending on the needs of the geographic location. A person skilled in the art will recognize the different methods of transferring weather data from weather stations 604 to processing server 612, and will also recognize the different intervals of which to transfer weather data from weather stations 604 to processing server 612. In the embodiment that is shown in FIG. 7, where intermediate server 624 is shown, weather stations 604 may gather weather data at predetermined intervals to be logged at intermediate server 624. Intermediate server 624 may then either send the logged weather data to processing server 612 at another predetermined interval or processing server 612 may query or request weather data from intermediate server 624 at another predetermined interval. By having intermediate server 624 present, the predetermined interval of gathering weather data by sensors of weather stations 604 need not match the predetermined interval of transferring weather data from intermediate server 624 to processing server 612. However in this embodiment, it would be preferred that the predetermined interval of sensors gathering weather data is either the same time interval or a shorter time interval in comparison to the time interval at which weather data is transferred from intermediate server 624 to processing server 612. A person skilled in the art will recognize the different methods of transferring weather data from weather stations 604 to processing server 612 in an embodiment with intermediate server 624. A person skilled in the art will also recognize the different intervals of which to gather whether data at weather stations 604 and the different intervals to transfer weather data between intermediate server 624 and processing server 612.

Returning to the embodiment of FIG. 6, and method 900 of FIG. 9, while weather data is being collected and transferred from weather stations 604 to processing server 612, other data, such as historical load data and renewable energy data, is also being queried and being received by processing server 612. At block 920, historical electrical load data is queried and received by processing server 612. The historical electrical load data represents the amount of electricity that is used for a given target geographic location. This data is required for when the AI engine 816 uses training model 820 it must determine what the input weather data is and what the predicted output electrical load data should be.

At block 925, historical electrical load data may need to be modified to remove any existing noise in the data itself. Noise in the data may result from many different reasons including, but not limited to, faulty meters, outlier points, and high spike usage in power that may not reflect normal trends in electrical load data. For example, high spike usage in power may be due to industries that use high power during irregular periods that may not be affected by weather. The mining of cryptocurrency is one such example industry, where computer mining rigs and mining computers may use a huge amount of electricity but their use is dictated by internet traffic and the need at different times for hash calculation. As such the usage of electrical power loads by cryptocurrency agencies and industries may be filtered out for more accurate results in predicted load data.

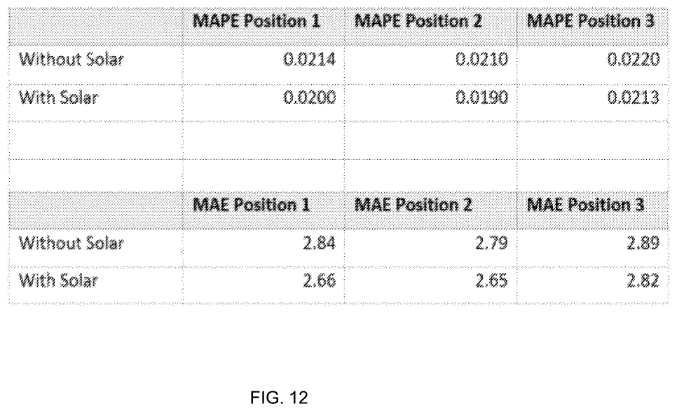

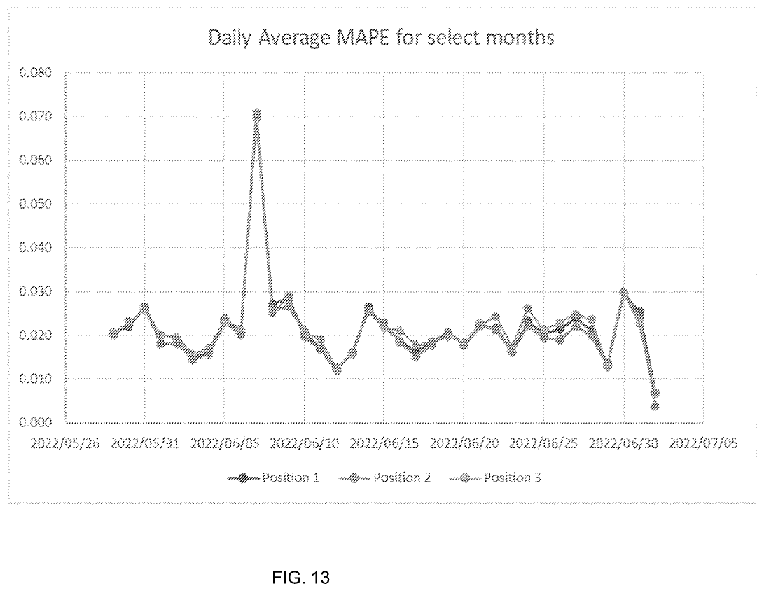

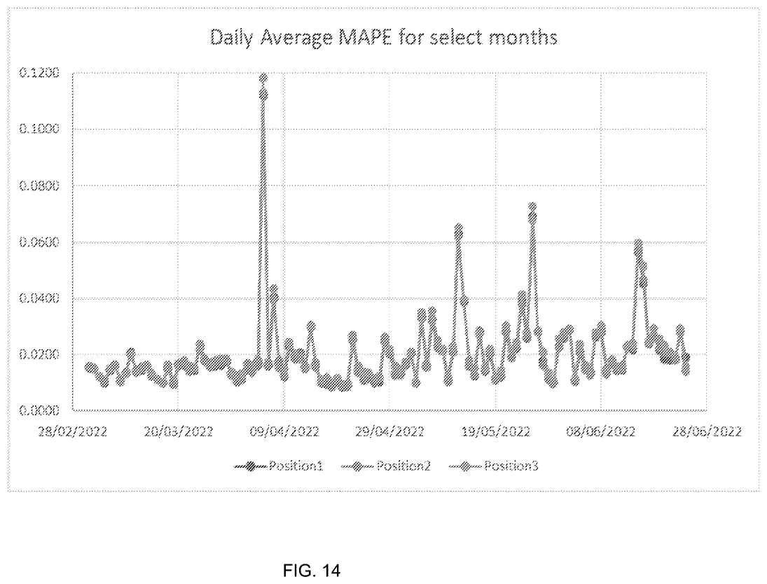

At block 930, another source of data may also be introduced from external databases 616, in this embodiment renewable energy data is received by processing server 612. Renewable energy data includes data that represents electrical loads or power generation from renewable energy sources that may or may not be local to the target geographic location. Renewable energy may be purchased by electrical power grids on a as needed basis, and as such this data may be incorporated to better provide a more accurate training model 820 so as AI engine 816 can provide a better and more accurate predicted load data. As can be seen in in FIG. 12, the mean absolute error values and mean absolute percentage error values of training models 820 with renewable solar energy and without renewable solar energy are provided. The values with renewable solar energy have a lower mean absolute error, meaning that it is more accurate. Similarly, the same can be seen in FIGS. 13 and 14, where FIG. 13 depicts the mean absolute percentage error over a period of several months without renewable solar energy included, and FIG. 14 depicts the mean absolute percentage error over a period of several months with renewable solar energy included. A person skilled in the art will recognize that while not depicted in this method 900, any source of data including renewable energy data, may need to be properly formatted before being used in training model 820.

In other embodiments, other sources of data from external databases 616 include energy price data.

Returning to FIG. 9. at block 935, the weather data, the cleaned electrical load data, and the renewable energy data may be normalized and standardized to be used in training model 820. Weather data from different sensors of weather stations 604 maybe calibrated differently. For example, what temperature sensor on a specific weather station 604, maybe calibrated differently and provide a different temperature than another temperature sensor that may be located in the same location. Alternatively, this may also be true when dealing with sensors of different manufacture. As such, data will need to be normalized before providing to training model 820. In addition weather data and any other data may also need to be formatted and standardized before being provided to create training model 820.

At block 940, the training model 820 is created using the normalized weather data, electrical load data, and renewable energy data. At block 945 test weather data is provided to AI engine 816 running the recently created training model 820. By providing test weather data a test predicted load data can be output from AI engine 816 using training model 820. At block 950, the output predicted test load data may be compared to the actual proper load data to determine the accuracy of training model 820. If the predicted load data from AI engine 816 does not match the actual load data in this test scenario, then training model 820 is not accurate and may need to be adjusted. In this scenario, it is likely that the weather stations 604 were not deployed in proper locations. As such weather stations 604 may need to be redeployed in different locations or moved to optimize the weather data gathered in said locations. Referring to FIG. 9, if the test data is not within tolerance against the expected load data, method 900 returns to block 910 to redeploy weather stations in new locations.

If at block 950 the test data is within tolerance against expected load data, then method 900 may continue onwards towards block 955 where the training model 820 may be deployed to be used by AI engine 816 in its normal operation.

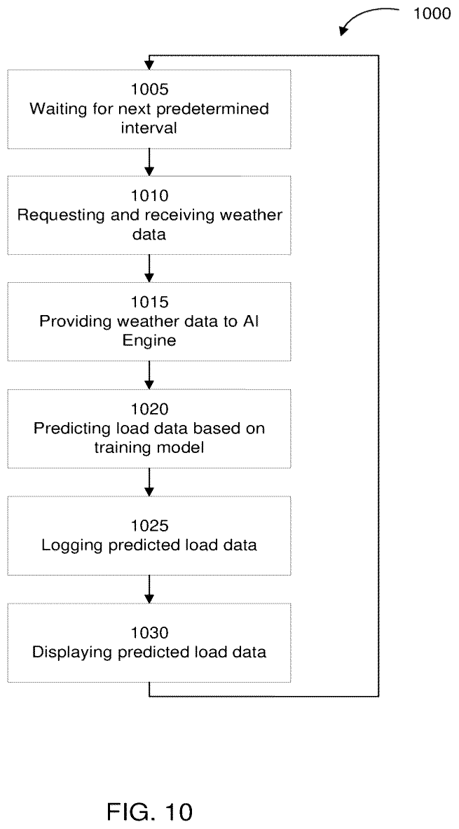

Referring to FIG. 10, method 1000 is depicted, where method 1000 shows the normal operation of AI engine 816 when predicting electrical load data based on received input of weather data from weather stations 604.

At block 1005, processing server 612 awaits the transfer of weather data from weather stations 604. As previously indicated, weather data may be transferred from weather stations 604 to processing server 612 at predetermined intervals. A person skilled in the art will recognize that predetermined intervals is an adjustable variable and maybe based on environmental conditions and/or the frequency of need of the predicted electrical load data.

At block 1010, the transfer of weather data from weather stations 604 to processing server 612 occurs. In the current embodiment, processing server 612 may request or query for the data from weather stations 604 and then received the data subsequently. As previously indicated, there are other methods of transferring the weather data from weather stations 604 to processing server 612, including weather stations 604 sending weather data automatically at predetermined intervals. A person skilled in the art will recognize the different methods of transferring weather data from weather stations 604 to processing server 612 and also will recognize the different time intervals upon which weather data may be transferred.

At block 1015, they're received weather data from weather stations 604 is provided to AI engine 816 to be analyzed and. At block 1020, AI engine 816 uses training model 820 to predict the expected electrical load data for a geographic location. When AI engine 816 predicts the expected electrical load data, it may do so based on variables within training model 820, which include the accuracy and/or the maximum time frame upon which the expected electrical load data is to be predicted out to. For example, when creating training model 820 or as a variable within AI engine 816, a maximum time frame of 3 days maybe set. In doing so, AI engine 816 will only predict electrical load data between the time that weather data is received till the maximum time frame of 3 days. The predicted load data may then be graphed out later on when displayed at blocks 1030, or specific points in time within the next 3 days may be queried and then displayed. An example of this will be further describe below.

Upon the prediction of expected electrical load data for a geographic location, the predicted load data is logged in memory 812. This is depicted at block 1025.

At block 1030, the expected electrical load data may be displayed on an output device such as a monitor. Alternatively the expected electrical load data may be displayed via a GUI or front end interface that may be accessed through client device 608. In an alternate embodiment, the logged predicted electrical load data may be queried from a front end interface from any remote device or client device 608.

Upon completion of delivering predicted electrical load data, or logging predicted load data, method 1000 returns to block 1005, where processing server 612 will await the next set of weather data from weather stations 604 at the next predetermined time interval.

The following example may provide better clarity. In this example, weather data is sent from weather stations 604 to processing server 612 every hour, and the expected duration of prediction for predicted electrical load data is 4 days. If AI engine 816 receives weather data at 3:00 p.m. on Monday, and is expected to predict electrical load data for next 4 days, it will predict electrical load data from 3:00 p.m. on Monday till 3:00 p.m. on Friday. This data is then logged. At the next predetermined interval at 4:00 p.m. on Monday, AI engine 816 of processing server 612 will once again receive weather data from weather stations 604, and will predict electrical load data from 4:00 p.m. on Monday till 4:00 p.m. on Friday. This new predicted electrical load data is then logged as well.

Depending on when a user queries for a predicted load data, unless otherwise specifically requested, the latest predicted load data will be used. The user may select the predicted load data for a specific point in time within the next 4 days, or the user may request the predicted load data for a time frame be shown on a graph. For example, if a user requests the predicted load data at 3:30 p.m. on Monday, and requests the predicted load data for 4:00 p.m. on Tuesday, the first example set of data provided above (the predicted load data between 3:00 p.m. on Monday and 3:00 p.m. on Friday) may be queried to provide the user with the result.

When selecting the maximum time frame upon which to provide predicted load data up until, it should be recognized that the larger the time span to predict electrical load data, the lesser the accuracy the further out in time the prediction is required. As an example, a predicted load data at 14 days is going to be less accurate than a predicted load data of 3 days using today's weather data. A person skilled in the art will recognize the different variations and configurations upon which low data may be predicted in method 1000, the variables that may be adjusted to provide a requested output, and how the adjustments may affect the accuracy of the predicted loud data.

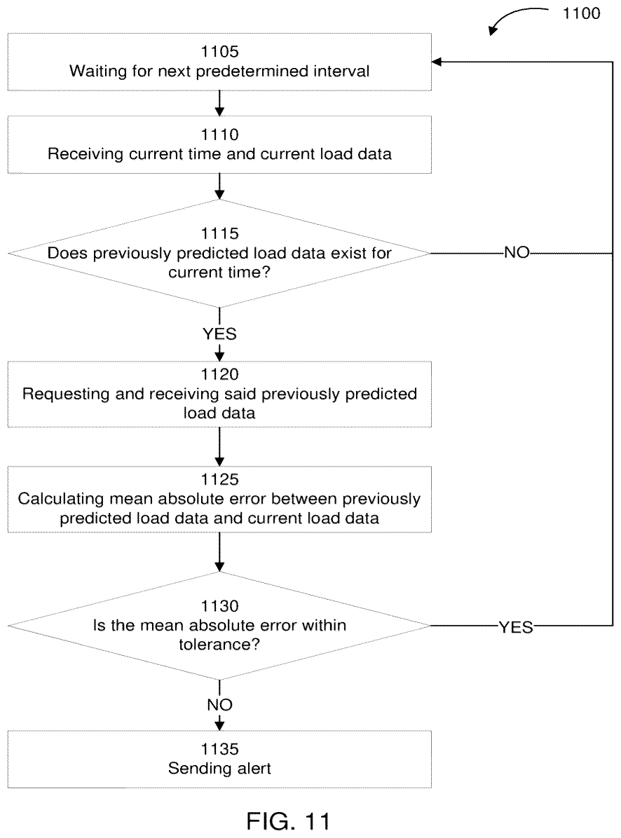

Referring to FIG. 11, method 1100 is shown, where method 1100 depicts the monitoring of the accuracy of training model 820 as time goes on.

At block 1105, processing server 612 is waiting for the next predetermined interval. This predetermined interval may be the same predetermined interval as previously provided in descending of weather data from weather stations 604 to processing server 612, and may be the same predetermined interval that weather data is provided to AI engine 816. In alternate embodiments this predetermine interval may be a different time frame. At block 1110, the current time stamp and the current electrical load data may be received from external databases 616. This transfer of current electrical load data may be requested from processing server 612, by processing server 612 sending a query with the current time stamp.

At block 1115, if predicted electrical load data exists for the current time stamp, processing server 612 may request and receive said previously predicted electrical load data from memory 812. This is depicted at block 1120. If at block 1115, the predicted electrical load data does not exist for the current timestamp, processing server 612 may return to block 1105 to a weight that the next predetermined interval.

At block 1125, after the receipt of predicted load data for the current time stamp, processing server 612 make calculate the mean absolute error between the previously predicted load data received at block 1120, and the current load data received at block 1110. The mean absolute error allows a calculation of the accuracy of training model 820.

At block 1130, if the mean absolute error is within tolerance, then training model 820 is still accurate and may continue to be used by AI engine 816 to provide predicted electrical load data. In the scenario, processing server 612 will return to block 1105 to wait for the next predetermined interval to check the accuracy of training model 820 again. Processing server 612 may also provide confirmation in the form of a logged entry or a message to a user, that the training model continues to be accurate.

Returning to block 1130, if the mean absolute error is outside of tolerance, then training model 820 is no longer accurate and as such may need to be adjusted. Reasons for why training model 820 may no longer be accurate may be a result of change in an environmental conditions surrounding the placement of weather stations 604, or faulty sensors on weather stations 604. When determining the reason for a training model 820 no longer being accurate, sensor data points may be examined. For example, a training model 820 made no longer be accurate if weather stations 604 was placed on top of a building and a new building was built adjacent to it blocking sunlight and wind from reaching weather stations 604. Other reasons for training model 820 no longer being accurate may also include if data sources from external databases 616 are no longer accurate from when the data was initially used to create training model 820. A person skilled in the art will recognize the various reasons upon which training model 820 may no longer be accurate after a period of time of operation.

If training model 820 is no longer accurate because the mean absolute error is outside tolerance, then at block 1135 and alert may be sent to administrator users, alerting them to the fact that training model 820 may need to be adjusted. Other forms of action should mean absolute error be outside of tolerance may also be contemplated such as automatically putting a stop to the use of training model 820.

In order to prevent corruption of training model 820, in the event that training model 820 may be adjusted or may still be able to be used despite a mean absolute error being outside of tolerance, the dynamic training of training model 820 may also be stopped. Dynamic training of training model 820 may occur at predetermined intervals, where the weather data that was used to create predicted electrical load data, and the actual load data may be fed to training model 820 to provide training model 820 with better accuracy in its use with AI engine 816. For better clarity and example is provided below.

For example, if dynamic training of training model 820 occurs every 12 hours, then any data that is monitored where mean absolute error is within tolerance, maybe fed to training model 820 every 12 hours to allow AI engine 816 to learn and improve its accuracy. However any data that is monitored where mean absolute error is outside of tolerance maybe pulled to prevent AI engine 816 from learning incorrect data hence reducing its accuracy.

In the event that a training model 820 is too far corrupted, or in the event of too many variables being changed, such as environmental conditions, then training model 820 may need to be regenerated using model generator 824. A new training model 820 may be required when either a change in the geographic location, a change in the size of the geographic location, and increase in the number of weather stations 604, or a development project that may drive significant economic or population activity in said geographic location that may significantly impact or obstruct weather measurements at the optimal locations for weather stations 604. A person skilled in the art will recognize other potential scenarios where a new training model 820 may be required.

Although this disclosure has described and illustrated certain preferred embodiments. As shown in FIGS. 1 to 14 of the invention, it may be understood that the invention may be not restricted to those embodiments. Rather, the invention includes all embodiments which are functional or mechanical equivalence of the specific embodiments and features that have been described and illustrated.

We claim:

1. A system for forecasting an energy load within a utility grid based on tuned weather data, the system comprising:
(a) a network of load sensitive weather instruments for producing tuned weather data;
(b) a processor linked to the network of load sensitive weather instruments and receiving the tuned weather data;
wherein the processor obtains the tuned weather data from the network of load sensitive weather instruments and is configured to analyse a utility grid specification and correlate the utility grid specification with the tuned weather data to forecast the energy load within the grid.

2. The system of claim 1 wherein factors of the utility grid comprise the configuration of electrical circuits in the utility grid, advanced metering infrastructure, a geographic area, time zones, micro-climatological area, historical load data, day of the week, holidays, behind the meter renewable generation, and electricity prices.

3. The system of claim 2 wherein the tuned weather data comprises storm warnings, wind speed, air density, irradiance, atmospheric turbulence, rain condition, snow condition, air temperature, and humidity.

4. The system of claim 3 wherein the processor employs a predictive artificial intelligence or neural network.

5. The system of claim 4 wherein the load sensitive weather instruments comprise an anemometer, an air densimeter, a hygrometer, a thermometer, a rain sensor, a snow sensor, or a turbulence sensor.

6. A process for the selection of load sensitive locations for a plurality of weather instruments, the process comprising:
(a) a first processor selecting potential locations for the plurality of weather instruments in order to minimize the difference in a predicted evapotranspiration (ETi) and a referenced theoretical evapotranspiration (ET0) at each of the potential location to produce an initial selection of locations;
(b) obtaining weather data for each of the initial selection of locations and transmitting the weather data to a second processer;
(c) a second processor receiving the weather data from the initial selection of locations and designing a machine learning model architecture and ensemble based on the weather data arriving at a load model design in order to minimize a mean absolute error (“MAE”) of a predicted load and an actual load at each locations of the initial selection of locations and the second processor assigning a weight to the weather data to produce weighted weather data in the process of designing a machine learning model architecture and ensemble; and
(d) the second processor transmitting the MAE and the weighted weather data to the first processor and the first processor observing the weighted weather data at each location of the initial selection of locations and assessing each location of the initial selection of the locations and based thereon selecting further potential locations in order to optimize the initial selection of locations in step (a) and repeating steps (b), (c) and (d) until an equilibrium is found where neither processor has an incentive to change their selections arriving at the load sensitive locations for the plurality of weather instruments.

7. The process of claim 6 wherein in step (c), the equilibrium is found where neither processor has an incentive to change their selections arriving at the suitable locations for the plurality of weather instruments and a final load model design.

8. A system for forecasting an electrical load within a utility grid, the system comprising:
at least one weather station, the at least one weather station configured to gather weather data;
a processor connected to the at least one weather station, the processor configured to receive weather data;
wherein the processor comprises a machine learning engine configured to forecast electrical load within a utility based grid on the received weather data, the machine learning engine comprising a training model, the training model generated based on a correlation of weather data from the at least one weather station to electrical load data.

9. A method for generating a training model for a machine learning engine to forecast an electrical load within a utility grid, the method comprising:
deploying at least one weather station in a first position;
receiving at a processor, weather data from the at least one weather station for a time frame;
receiving at the processor, electrical load data within the utility grid for the time frame;
normalizing, by the processor, the weather data and electrical load data;
creating by the processor the training model based on the normalized weather data and electrical load data;
calculating a mean absolute error to determine accuracy of the training model;
if the mean absolute error is not within a tolerance, re-deploying the at least one weather station in a second position; and
if the mean absolute error is within the tolerance, deploying the training model to the machine learning engine.

10. A method for forecasting an electrical load within a utility grid, the method comprising:
receiving at a processor, weather data from at least one weather station at a predetermined time interval; and
forecasting an electrical load within a utility grid using a machine learning engine of the processor, the machine learning engine configured to forecast electrical load within a utility based grid on the received weather data, the machine learning engine comprising a training model, the training model generated based on a correlation of weather data from the at least one weather station.

11. A method for monitoring a training model of a machine learning engine, the machine learning engine configured to forecast an electrical load within a utility grid, the method comprising:
receiving an electrical load for the utility grid for a time frame;
receiving a previously predicted electrical load for the utility grid for the time frame;
calculating a mean absolute error between the electrical load for the utility grid and the previously predicted electrical load;
if the mean absolute error is within a tolerance, providing confirmation that the training model is accurate; and
if the mean absolute error is not within the tolerance, sending an alert that the training model is not accurate.

12. A system for anticipating an energy load within a utility grid during a predetermined time interval, the system comprising:
a load sensitive weather instrument for detecting and transmitting weather data during the predetermined time interval;
a processor operatively connected to the load sensitive weather instrument and configured to receive the weather data, the processor further comprising a load prediction engine;
wherein the processor receives the weather data and passes the weather data through the load prediction engine to determine an anticipated energy load within the utility grid during the predetermined time interval based a correlation between the weather data and pattern data and the processor further configured to transmit the anticipated energy load to a user.

13. The system of claim 12 wherein the pattern data comprises, historical energy load data, day of the week data, holiday data, renewable energy generation data and energy price data.

14. The system of claim 13, wherein the predictive engine being trained using historic weather data and historic energy load data employed by an artificial intelligence-based module.

15. The system of claim 14 wherein the load sensitive weather instrument comprises an anemometer, an air densimeter, a hygrometer, a thermometer, a rain sensor, a snow sensor, or a turbulence sensor.

16. The system of claim 15 further comprising a server in communication with the processor to receive the anticipated energy load from the processor and in communication with a client device to transmit the anticipated energy load as an output to the client device, the client device displaying the anticipated energy load to a user.

17. A process for anticipating an energy load within a utility grid during a predetermined time interval, the process comprising:
detecting and transmitting weather data during the predetermined time interval from a load sensitive weather instrument;
receiving the weather data at a processor operatively connected to the load sensitive weather instrument and configured to receive the weather data, the processor further comprising a load prediction engine;
passing the weather data through the load prediction engine to determine an anticipated energy load within the utility grid during the predetermined time interval based a correlation between the weather data and pattern data.

18. The process of claim 17 wherein the pattern data comprises, historical energy load data, day of the week data, holiday data, renewable energy generation data and energy price data.

19. The process of claim 18, wherein the predictive engine being trained using historic weather data and historic energy load data employed by an artificial intelligence-based module.

20. The process of claim 19 wherein the load sensitive weather instrument comprises an anemometer, an air densimeter, a hygrometer, a thermometer, a rain sensor, a snow sensor, or a turbulence sensor.

21. The process of claim 20 further comprising the processor transmitting the anticipated energy load to a server and the server transmitting the anticipated energy load as an output to a client device, the client device displaying the anticipated energy load to a user.
